(19) United States
(12) Patent Application Publication
(10) Pub. No.: US 2016/0135560 A1
(43) Pub. Date: May 19, 2016

(54) PROTECTION COVER

(71) Applicant: HON HAI PRECISION INDUSTRY CO., LTD., New Taipei (TW)

(72) Inventor: GUO-LIANG YEH, New Taipei (TW)

(21) Appl. No.: 14/716,649

(22) Filed: May 19, 2015

(30) Foreign Application Priority Data
Nov. 13, 2014 (TW) 103220176

(51) Int. Cl. A45C 11/00; H05K 5/00

(52) U.S. Cl. CPC A45C 11/00; H05K 5/0086; H05K 5/0013; A45C 2011/002; A45C 2011/003

(57) ABSTRACT

A protection cover includes a first shell, a second shell, and a plurality of connecting members. The first shell includes a bottom plate and two or more side walls positioned on opposite ends of the bottom plate. The bottom plate and the two or more side walls cooperatively define a receiving cavity configured to receive the portable electronic device. The second shell is fastened to a side of the bottom plate away from the side walls via the connecting members.

### FIELD

The subject matter herein generally relates to protection covers.

### BACKGROUND

Portable electronic devices such as mobile phones, tablet computers and so on, are vulnerable to scratches and other damage. Therefore, a protection cover covering the electronic device is necessary for protection. An internal structure is usually assembled in the electronic device for the convenient installation of the protective cover.

### BRIEF DESCRIPTION OF THE DRAWINGS

Implementations of the present technology will now be described, by way of example only, with reference to the attached figures.

FIG. 1 is an isometric view of an embodiment of a protection cover.

FIG. 2 is an isometric view of a first shell of the protection cover of FIG. 1.

FIG. 3 is an isometric view of the first shell of the protection cover of FIG. 2 from another perspective.

FIG. 4 is an isometric view of a second shell of the protection cover of FIG. 1.

FIG. 5 is an isometric view of the second shell of the protection cover of FIG. 4 from another perspective.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”, it specifically indicates open-ended inclusion or membership in the so-described combination, group, series and the like.

The present disclosure is described in relation to a protection cover.

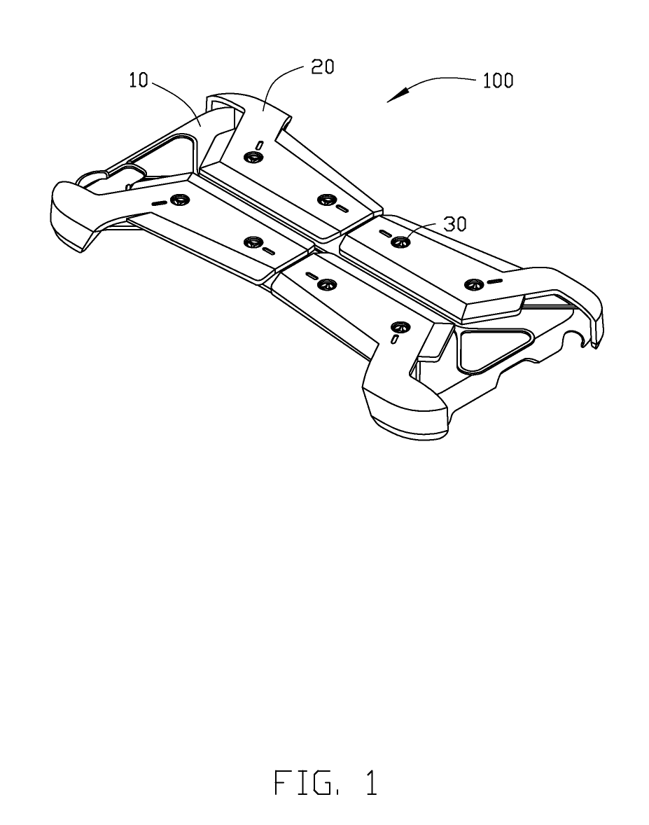

FIG. 1 illustrates an embodiment of a protection cover 100 configured to protect to a portable electronic device (not shown), such as mobile phones, tablet computers and so on. The protection cover 100 can be substantially X shaped, and can include a first shell 10, a second shell 20, and a plurality of connecting members 30. The first shell 10 can be configured to receive the portable electronic device (not shown). The second shell 20 can be configured to receive the first shell 10. The first shell 10 can be fastened to the second shell 20 via the connecting members 30.

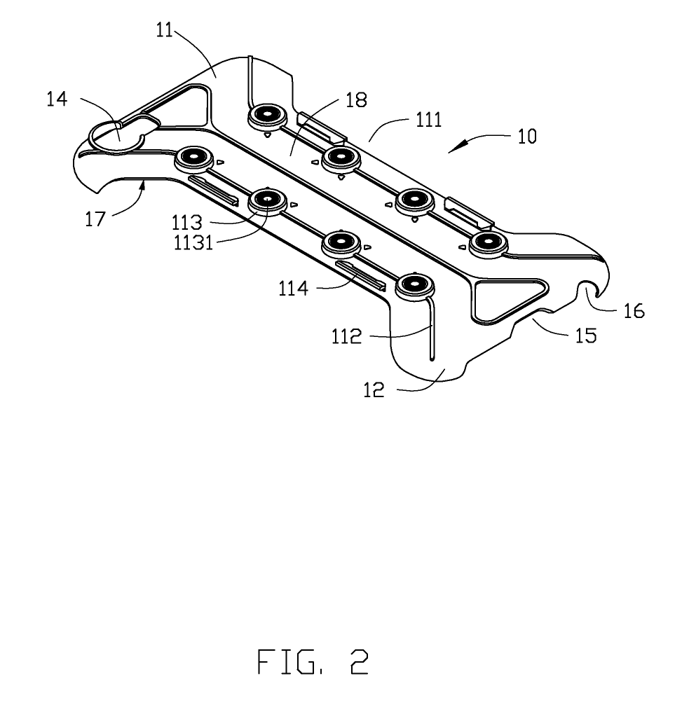

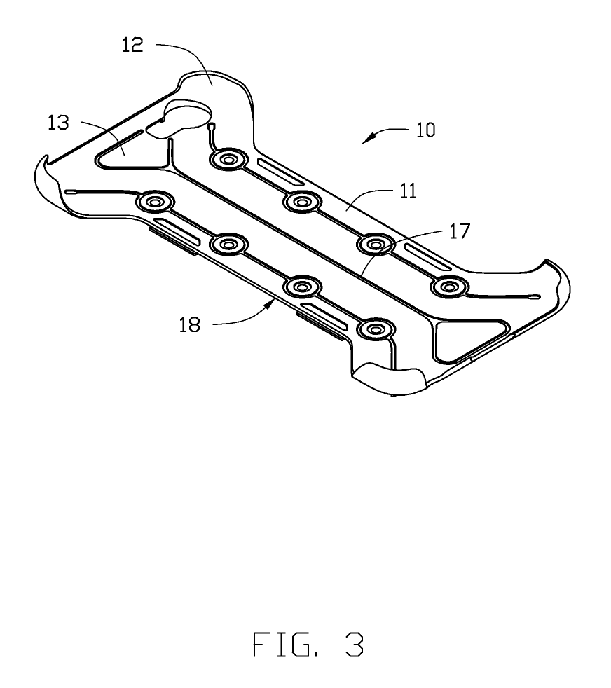

FIGS. 2 to 3 illustrate that the first shell 10 can include a bottom plate 11, two or more side walls 12 positioned on opposite ends of the bottom plate 11, a first inner side 17 and a first outer side 18 opposite to the first inner side 17. The two or more side walls 12 can extending away from the first inner side 17 of the bottom plate 11. The first inner side 17 of the bottom plate 11 and the two or more side walls 12 can cooperatively define a receiving cavity 13 configured to receive the portable electronic device (not shown). Two recesses 111 can be defined on opposite sides of the bottom plate 11. A through hole 14 can be defined on the bottom plate 11 adjacent to a side wall 12. The through hole 14 can be configured to receive a camera of the portable electronic device (not shown). A first gap 15 and a second gap 16 can be defined on one side wall 12. The first gap 15 can be configured to expose a power interface of the portable electronic device (not shown). The second gap 16 can be configured to expose a headset jack of the portable electronic device (not shown).

The bottom plate 11 can include at least one rib 112 and at least one projection stage 113 positioned on the rib 112, and a plurality of sliding rails 114. The rib 112, the projection stage 113, and the sliding rails 114 can be positioned on the first outer side 18 of the bottom plate 11. A shape of the projection stage 133 can be substantially circular. A first hole 1131 can be defined on a free end of each of the at least one projection stage 113. In the illustrated embodiment, the first hole 1131 can be a threaded hole. The sliding rails 114 can be adjacent to the at least one projection stage 113 and can be parallel to an edge of the bottom plate 11. A number of the sliding rails 114 can be four.

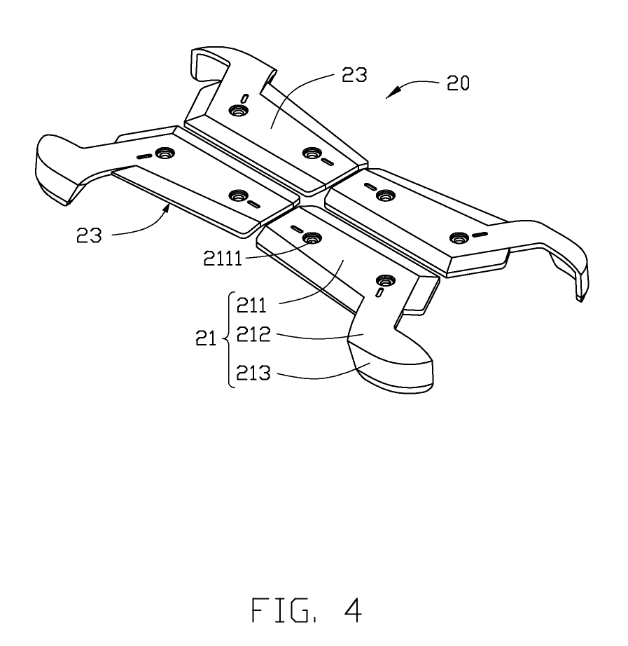

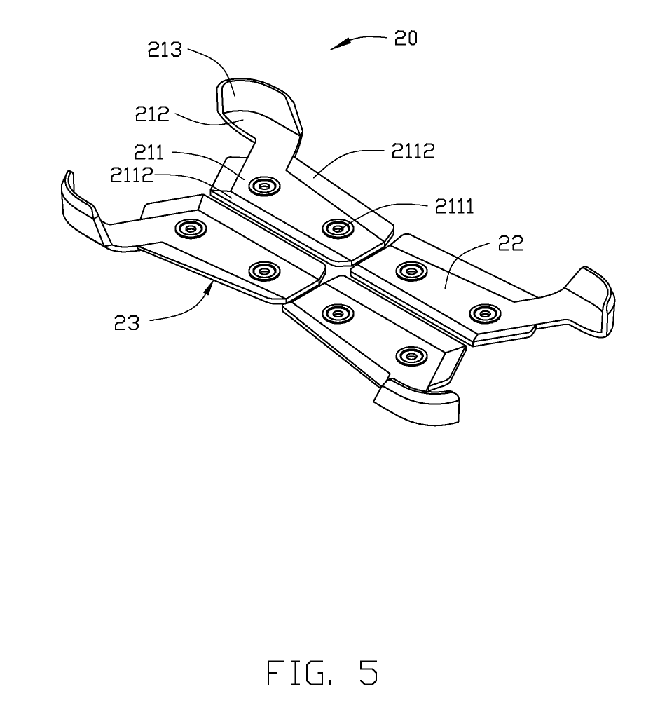

FIGS. 4 to 5 illustrate that the second shell 20 can include four shell assemblies 21, a second inner side 22 and a second outer side 23 opposite to the second inner side 22. The second shell 20 can be configured to receive the first shell 10 with at least a portion of the second inner side 22 of the second shell 20 abutting at least a portion of the first outer side 18 of the first shell 10. The four shell assemblies 21 can be arranged centrosymmetrical. Each of the shell assemblies 21 can include a main body 211, an extending portion 212, and a latching portion 213. A shape of the main body 211 can be substantially rectangular. The extending portion 212 can obliquely extend from a corner (not labeled) of the main body 211. The latching portion 213 can be vertically positioned on and extend from an edge of the extending portion 212 away from the main body 211. The latching portion 213 can be parallel to the two or more side walls 12 (shown in FIG. 2). At least one second hole 2111 can be defined on the main body 211 and correspond to the first hole 1131 (shown in FIG. 2). The at least one second hole 2111 can be a threaded hole.

In the illustrated embodiment, the main body 211 can include a plurality of inclination walls 2112 obliquely extending from opposite sides of the main body 211. The inclination walls 2112 can correspond to the sliding rails 114 (shown in FIG. 2). The inclination walls 2112 can be coupled to the sliding rails 114 to allow easy assembly and disassembly of the shell assemblies 21 with the first shell 10 (shown in FIG. 2).

In assembly, each of the shell assemblies 21 can be fastened on the first outer side 18 of the first shell 10, via at least one connecting member 30 passing through the second holes 2111 and the first holes 1131. The latching portion 213 of each shell assembly 21 can resist against a corner (not labeled) of the two or more side walls 12 to allow the first shell 10 to be received in the second shell 20. Thereby, the second shell 20 can protect the first shell 10.

In use, the portable electronic device (not shown) can be received in the receiving cavity 13 of the first shell 10 for protection.

In other embodiments, the shape and the number of through holes 14, first gaps 15, and second gaps 16 can be changed according to the portable electronic device (not shown) received in the first shell 10.

In other embodiments, the second shell 20 can be connected to the first shell 10 by other connecting means, such as snap joint connection.

As described above, the first shell 10 can be received in and can be fastened to the second shell 20. Therefore, the portable electronic device (not shown) received in the first shell 10 can be further protected.

The embodiments shown and described above are only examples. Many details are often found in the art such as the other features of a protection cover. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A protection cover comprising:
a first shell having a first inner side and a first outer side, the first shell outer side being opposite to the first shell inner side;
a second shell having a second inner side and a second outer side, the second shell outer side being opposite to the second shell inner side; and
a plurality of connecting members;
wherein the first shell includes a bottom plate and two or more side walls positioned at opposite ends of the bottom plate and extending away from the first inner side of the bottom plate, with the first inner side of the bottom plate and the two or more side walls cooperatively defining a receiving cavity configured to receive a portable electronic device;
wherein the second shell is configured to receive the first shell with at least a portion of the second inner side of the second shell abutting at least a portion of the first outer side of the first shell; and
wherein the connecting members fasten the first shell to the second shell.

2. The protection cover as claimed in claim 1, wherein the second shell further comprises four shell assemblies, each of the shell assemblies comprises a main body, an extending portion, and a latching portion, the extending portion obliquely extends from a corner of the main body, and the latching portion vertically extends from and is positioned on an end edge of the extending portion away from the main body.

3. The protection cover as claimed in claim 2, wherein the four shell assemblies are arranged centrosymmetrical, and the four latching portions resist against the side walls of the first shell.

4. The protection cover as claimed in claim 2, wherein at least one first hole is defined on the bottom plate, and at least one second hole is defined on the main body of each shell assembly and corresponds to the first hole.

5. The protection cover as claimed in claim 4, wherein each of shell assemblies is fastened to the first shell via at least one connecting member passing the second hole and the first hole.

6. The protection cover as claimed in claim 4, wherein at least one rib is positioned on the first outer side of the bottom plate, and the first hole is defined on the rib.

7. The protection cover as claimed in claim 6, wherein at least one projection stage is positioned on the rib, and the first hole is defined on the at least one projection stage.

8. The protection cover as claimed in claim 6, wherein the bottom plate comprises a plurality of sliding rails, and the sliding rails are positioned on the first outer side of the bottom plate.

9. The protection cover as claimed in claim 6, wherein the main body comprises a plurality of inclination walls obliquely extending from opposite sides of the main body, and the inclination walls are coupled to the sliding rails to allow easy assembly and disassembly of the shell assemblies with the first shell.

10. The protection cover as claimed in claim 1, wherein two recesses are defined on opposite sides of the bottom plate.
